(19) United States
(12) Patent Application Publication
(10) Pub. No.: US 2026/0353928 A1
(43) Pub. Date: Nov. 5, 2026

(54) ORGANIC LIGHT-EMITTING DISPLAY DEVICE

(71) Applicants: Byungchul Ahn, Seoul (KR); YAS CO., LTD., Gyeonggi-do (KR)

(72) Inventor: Byungchul Ahn, Seoul (KR)

(21) Appl. No.: 19/487,989

(22) PCT Filed: Aug. 2, 2024
(86) PCT No.: PCT/KR2024/011449

§ 371 Date: Nov. 25, 2025

(30) Foreign Application Priority Data
Aug. 4, 2023 (KR) 10-2023-0102412
Nov. 9, 2023 (KR) 10-2023-0154628
Jun. 11, 2024 (KR) 10-2024-0075900
Jul. 17, 2024 (KR) 10-2024-0094563
Aug. 2, 2024 (KR) 10-2024-0103098

(51) Int. Cl. H10K 59/122; H10K 59/12; H10K 59/80

(52) U.S. Cl. CPC H10K 59/122; H10K 59/1201; H10K 59/80522

(57) ABSTRACT

An organic light-emitting display device may include a bank between subpixels on a substrate, an anode electrode on the subpixel, an organic light-emitting layer on the anode electrode and the bank, a cathode electrode on the organic light-emitting layer, and a protrusion part disposed on an upper side of the bank so as to be spaced apart from the organic light-emitting layer. The protrusion part may include an etch-stop layer comprising one of ITO, Al₂O₃, Cu, and CuOx on an uppermost side thereof.

### TECHNICAL FIELD

The embodiment relates to an organic light-emitting display device.

### BACKGROUND ART

As the demand for portable information media increases, an attempt to apply an organic light-emitting display device to various lightweight and thin information electronic devices is expanding. Recently, the organic light-emitting display device is being applied to product groups such as a mobile PC and an automobile rather than TV or a mobile phone. Since the organic light-emitting display device applied to the mobile PC and the automobile is driven as still image for a long time, long lifespan is required. In order to have the long lifespan, the extraction of light from the organic light-emitting element must be maximized. In addition, in order to reduce the cost, it is necessary to expand the technology to be able to produce organic light-emitting elements on a substrate 110 of not only 8.5^{th} generation (2200×2,500 mm) but also 10.5^{th} generation (3370×2940 mm). In order to produce long-life organic light-emitting element, each subpixel with a top emission structure and a side-by-side structure must be implemented as a structure of an organic light-emitting element with two or more stacks.

The structure of such an organic light-emitting element may be obtained through a deposition equipment using a fine metal mask (FMM, hereinafter referred to as FMM). However, the deposition method using FMM has the problem of low productivity because the production logistics must be produced only in a cluster method rather than an in-line method. In addition, there is a problem of low pixel position accuracy (PPA) between the FMM and the substrate. Accordingly, the emission area ratio (EAR) is small, which limits the product life. Here, the emission area ratio is the value obtained by dividing the emission area of the subpixel by the area of the subpixel. Therefore, the development of a new deposition method to solve the aforementioned problems and an organic light-emitting display device having a new organic light-emitting element structure using the new deposition method is very urgent.

### DISCLOSURE

### Technical Problem

An object of the embodiment is to solve the foregoing and other problems.

Another object of the embodiment is to provide an organic light-emitting display device having a novel structure.

Another object of the embodiment is to provide an organic light-emitting display device capable of improving the lifespan.

Another object of the embodiment is to provide an organic light-emitting display device capable of improving productivity and yield.

Another object of the embodiment is to provide an organic light-emitting display device capable of improving image quality.

The technical problems of the embodiments are not limited to those described in this item and comprise those that may be understood through the description of the invention.

### Technical Solution

According to one aspect of the embodiment to achieve the above or other objects, an organic light-emitting display device, comprising: a bank between subpixels on a substrate; an anode electrode on the subpixel; an organic light-emitting layer on the anode electrode and the bank; a cathode electrode on the organic light-emitting layer; a protrusion part disposed on an upper side of the bank so as to be spaced apart from the organic light-emitting layer, wherein the protrusion part comprises an etch-stop layer comprising one of ITO, Al₂O₃, Cu, and CuOx on an uppermost side thereof.

The protrusion part may have a connection structure comprising an auxiliary electrode electrically connected to the cathode electrode, and the etch-stop layer may be disposed on the connection structure.

The protrusion part may comprise a first layer on the bank; a second layer on the first layer; and a third layer below the first layer. A side portion of the third layer may be positioned on a same vertical line or diagonal line as a side portion of the second layer or may extend from a side portion of the second layer in a direction of the subpixel. A side portion of the first layer may be recessed into an inside of the protrusion part from the side portion of the second layer.

The etch-stop layer may be disposed on the second layer.

The etch-stop layer may surround the second layer.

The etch-stop layer may be disposed on the side portion and a lower side of the second layer.

The etch-stop layer may comprise a first etch-stop layer on the second layer; and a second etch-stop layer between the second layer and the first etch-stop layer.

The first etch-stop layer may be disposed on a lower side of the second layer via a side portion of the second etch-stop layer.

At least one of the first layer, the second layer, or the third layer may be the auxiliary electrode.

The protrusion part may comprise a seed layer and a plating layer on the seed layer. The plating layer may be the etch-stop layer.

The plating layer may have a width of an upper region thereof smaller than a width of a lower region thereof and have a rounded-shape mushroom structure at an edge of a surface of the upper region.

The protrusion part may further comprise a cover layer on the plating layer.

The organic light-emitting display device may further comprise an open structure configured to induce a hole injection layer of the organic light-emitting layer to be isolated in the bank.

### Advantageous Effects

The effects of the organic light-emitting display device according to the embodiment are described as follows.

According to at least one of the embodiments, there is an advantage that the process is simplified and the process cost can be reduced because there is no need to use an FMM.

According to at least one of the embodiments, there is an advantage that the EAR within the subpixel increases because there is no need to use an FMM, so that the lifespan can be improved.

According to at least one of the embodiments, there is an advantage that productivity, yield, and material utilization efficiency can be improved by depositing the organic light-emitting element on a large-area substrate in an in-line deposition system.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a schematic plan view illustrating an organic light-emitting display device according to a first embodiment.

FIG. 2 is a plan view illustrating one pixel of FIG. 1.

FIG. 3 is a circuit diagram illustrating an organic light-emitting display device according to the embodiment.

FIG. 4A is a cross-sectional view taken along line A-A′ in the pixel of FIG. 2.

FIG. 4B is a cross-sectional view taken along line B-B′ in the pixel of FIG. 2.

FIG. 4C is a cross-sectional view taken along line C-C′ in the pixel of FIG. 2.

FIG. 5 is a cross-sectional view illustrating an organic light-emitting display device according to the first embodiment.

FIGS. 6A to 6C illustrate a manufacturing process of an organic light-emitting display device according to the first embodiment.

FIG. 7 is a cross-sectional view illustrating an organic light-emitting display device according to a second embodiment.

FIGS. 8A to 8C illustrate a manufacturing process of an organic light-emitting display device according to the second embodiment.

FIG. 9 is a cross-sectional view illustrating an organic light-emitting display device according to a third embodiment.

FIG. 10 is a cross-sectional view illustrating an organic light-emitting display device according to a fourth embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

Hereinafter, an organic light-emitting display device having a side-by-side structure manufactured using a photolithography process is disclosed. This structure is called Ph-SbS (side-by-side structure by photolithography). By using the photolithography process, the process can be simplified and the process cost can be reduced because there is no need to use FMM. In addition, the EAR within the subpixel may be increased, so that the lifespan can be improved. In addition, since the organic light-emitting element is deposited on a large-area substrate in an in-line deposition system, productivity, yield, and material utilization efficiency can be improved.

Hereinafter, a red subpixel SPr may be named as a first subpixel, a green subpixel SPg may be named as a second subpixel, and a blue subpixel SPb may be named as a third subpixel. In addition, the red organic light-emitting element 120r may be named as a first organic light-emitting element, the green organic light-emitting element 120g may be named as a second organic light-emitting element, and the blue organic light-emitting element 120b may be named as a third organic light-emitting element.

Hereinafter, the organic light-emitting display device 100 is a top-emission type that displays an image by emitting light in the upper direction of the substrate 110, but a bottom-emission type that displays an image by emitting light in the lower direction of the substrate 110 may also be included in the technical idea of the present invention.

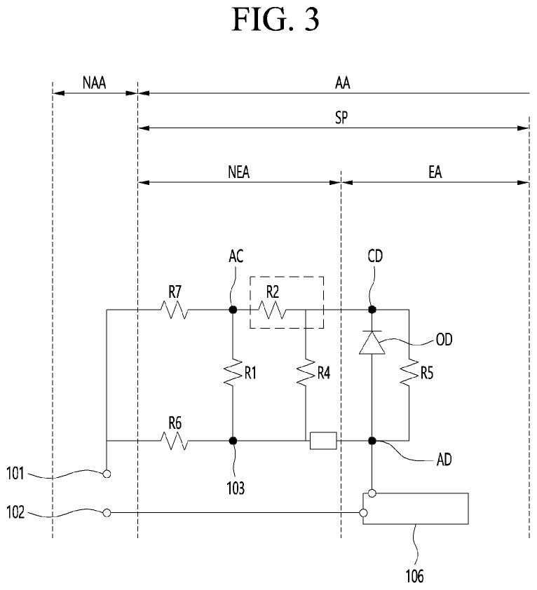

Hereinafter, the drawing number of the auxiliary electrode may be given as AC as illustrated in FIG. 3 unless a separate drawing symbol is given.

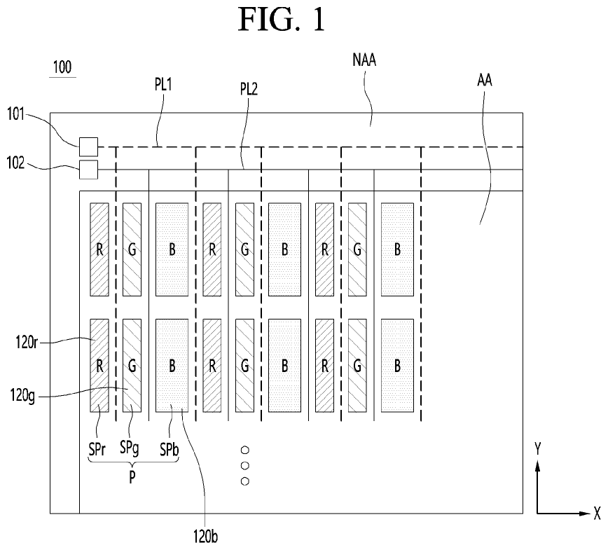

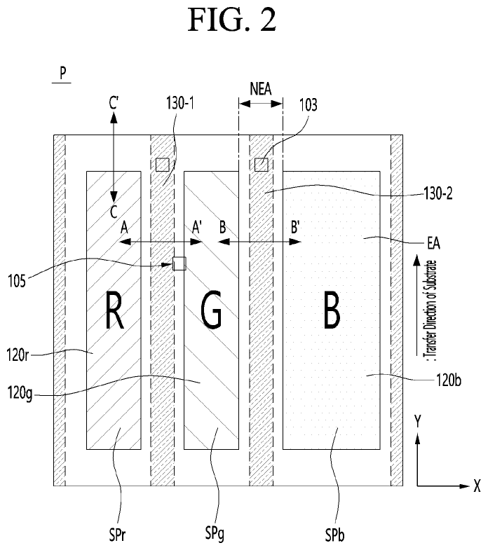

FIG. 1 is a plan view schematically illustrating an organic light-emitting display device according to a first embodiment. FIG. 2 is a plan view illustrating one pixel of FIG. 1.

Referring to FIGS. 1 and 2, the organic light-emitting display device 100 according to the first embodiment may comprise a plurality of pixels P arranged in a matrix. The plurality of pixels P may be positioned in a display region AA. An area remaining except for the display region AA may be a non-display region NAA.

Each pixel P may comprise, for example, a red subpixel SPr, a green subpixel SPg, and a blue subpixel SPb. For example, a red organic light-emitting element 120r may be disposed in a red subpixel SPr, a green organic light-emitting element 120g may be disposed in a green subpixel SPg, and a blue organic light-emitting element 120b may be disposed in a blue subpixel SPb. Although one pixel P comprising three subpixels SPr, SPg, and SPb is illustrated in the drawing, more subpixels may be included than these.

Although the drawing illustrates that the area of the blue subpixel SPb is greater than the area of the red subpixel SPr or the area of the green subpixel SPg, other variations are possible.

Each of the subpixels SPr, SPg, and SPb may comprise an emitting region EA and a non-emitting region NEA. The emitting region EA may be an area where the organic light-emitting element 120r, 120g, and 120b of each of the subpixels SPr, SPg, and SPb are disposed, and the non-emitting region NEA may be the remaining region excluding the emission region EA in each of the subpixels SPr, SPg, and SPb.

Meanwhile, a first power line PL1 and a second power line PL2 may be provided to supply power to each of the subpixels SPr, SPg, and SPb. A first power terminal 101 may be electrically connected to one end of the first power line PL1, and a second power terminal 102 may be electrically connected to one end of the second power line PL2. The first power terminal 101 and the second power terminal 102 may be electrically connected to a power supply unit (not illustrated) to receive a first potential voltage and a second potential voltage. The second potential voltage may be greater than the first potential voltage, and the first potential voltage may be grounded.

The first power line PL1 and the second power line PL2 may be disposed between the non-emitting region NEA along a first direction X. The first power line PL1 and the second power line PL2 may be electrically connected to each of the subpixels SPr, SPg, and SPb.

A contact pad 103 may be positioned in the non-emitting region NEA. The first power line PL1 may be electrically connected to the contact pad 103.

The auxiliary electrode (AC in FIG. 3) may be positioned in the non-emission region NEA. The auxiliary electrode AC may be positioned in the non-emission region NEA along a second direction Y, but is not limited thereto.

The auxiliary electrode AC may be positioned in the non-emission region NEA adjacent to each of the subpixels SPr, SPg, and SPb. The auxiliary electrode AC may be electrically connected to the first power line PL1 via the contact pad 103.

The first power line PL1, the contact pad 103, and the auxiliary electrode AC may be disposed in different layers.

The auxiliary electrode AC may be electrically connected to cathode electrodes of the adjacent organic light-emitting elements 120r, 120g, and 120b of the adjacent subpixels SPr, SPg, and SPb. For example, when the auxiliary electrode AC is positioned between the red subpixel SPr and the green subpixel SPg, the auxiliary electrode AC may be electrically connected to the cathode electrode of the red organic light-emitting element 120r and the cathode electrode of the green organic light-emitting element 120g.

Therefore, the auxiliary electrode AC may supply the first potential voltage from the first power line PL1 to the cathode electrodes of each of the organic light-emitting elements 120r, 120g, and 120b.

Meanwhile, the second power line PL2 may be electrically connected to a driving circuit 106 of each of the subpixels SPr, SPg, and SPb, for example, the driving transistor, but is not limited thereto. Accordingly, when a specific subpixel is selected in response to a scan signal provided through a specific gate line, light having a luminance corresponding to a current flowing in a driving transistor of the specific subpixel may be emitted by the first potential voltage of the first power line PL1 and the second potential voltage of the second power line PL2.

The plurality of organic light-emitting elements 120r, 120g, and 120b may be disposed in a stripe shape along the second direction Y. That is, the plurality of organic light-emitting elements 120r, 120g, and 120b may be disposed continuously without being separated along the second direction Y, respectively. For example, the red organic light-emitting element 120r may be disposed continuously along the second direction Y, the green organic light-emitting element 120g may be disposed continuously along the second direction Y, and the blue organic light-emitting element 120b may be disposed continuously along the second direction Y.

As another example, the plurality of organic light-emitting elements 120r, 120g, and 120b may be separated in pixel P units or row-line units along the second direction Y. That is, the red organic light-emitting element 120r may be separated in pixel P units or row-line units along the second direction Y, the green organic light-emitting element 120g may be separated in pixel P units or row-line units along the second direction Y, and the blue organic light-emitting element 120b may be separated in pixel P units or row-line units along the second direction Y.

The red subpixel SPr, the green subpixel SPg, and the blue subpixel SPb may be alternately arranged in column-line units along the first direction X. That is, the red subpixel SPr, the green subpixel SPg, and the blue subpixel SPb having different colors may be sequentially positioned along the first direction X to implement an organic light-emitting display device having a side-by-side structure.

Meanwhile, an asymmetric open-connection (AOC) structure 105 may be positioned in the non-emitting region NEA. In an embodiment, the asymmetric open-connection structure 105 may comprise a connection structure 105A and an open structure 105B. Due to the different ratios of depth and gap in the undercut structures of the connection structure 105A and the open structure 105B, it can be named as the asymmetric open-connection structure 105. The depth may represent a width in a horizontal direction of the undercut structure, and the gap may represent a width in a vertical direction of the undercut structure.

As will be described later, a lateral leakage current between a plurality of subpixels SPr, SPg, and SPb may be prevented by the asymmetric open-connection structure 105. The lateral leakage current may mean a leakage current flowing between adjacent subpixels SPr, SPg, and SPb along the first direction X. In addition, an electrical short between the anode electrode and the cathode electrode in the corresponding subpixels SPr, SPg, and SPb may be prevented by the asymmetric open-connection structure 105. Therefore, by using the asymmetric open-connection structure 105, color spot due to leakage current may be enhanced and luminescence efficiency and luminance may be significantly improved.

The connection structure 105A may be a structure that electrically connects the auxiliary electrode AC to the cathode electrode of each of the organic light-emitting elements 120r, 120g, and 120b. The open structure 105B may be a structure that separates layers comprising low-resistance organic light-emitting materials of each of the organic light-emitting elements 120r, 120g, and 120b, such as a hole injection layer, a charge generation layer, etc., thereby preventing electrical shorts between the anode electrode and the cathode electrode and reducing leakage current between the subpixels. The asymmetric open-connection structure 105 may also be called a ‘paradoxical open-connection’ structure.

FIG. 3 is a circuit diagram illustrating an organic light-emitting display device according to an embodiment. FIG. 3 may be a circuit diagram for an electrical connection from the first power terminal 101 and the second power terminal 102 to the green subpixel SPg in FIG. 2. The circuit diagram illustrated in FIG. 2 may be equally applied to a circuit diagram for an electrical connection from the first power terminal 101 and the second power terminal 102 to the red subpixel SPr or the blue subpixel SPb.

As illustrated in FIG. 3, the first power terminal 101 and the second power terminal 102 may be disposed in the non-display region NAA, and the first power line PL1 and the second power line PL2 may be disposed in the non-display region NAA and the display region AA.

The contact pad 103 may be disposed in the non-emission region NEA and may be electrically connected to the first power line PL1. The first power line PL1 may be electrically connected to the auxiliary electrode AC through the contact pad 103.

The organic light-emitting element 120g may be disposed in the emission region EA of the subpixel SPg, and the connection structure 105A and the open structure 105B may be disposed in the non-emission region NEA. The asymmetric open-connection structure 105 illustrated in FIG. 2 may be configured by the connection structure 105A and the open structure 105B. The auxiliary electrode AC may be electrically connected to the cathode electrode 123g of the organic light-emitting element 120g through the connection structure 105A. The hole injection layer of the organic light-emitting element 120g can be isolated through the open structure 105B, so that the anode electrode 121g and the cathode electrode 123g can be electrically disconnected.

As illustrated in FIG. 3, various resistances may be formed between each component. Each resistance may be defined as follows.

R1: Contact resistance between the contact pad 103 and the auxiliary electrode AC

R2: Resistance between the auxiliary electrode AC and the cathode electrode

R4: Resistance between the anode electrode 121g and the cathode electrode 123g due to the hole injection layer, etc., disposed in the horizontal direction

R5: Resistance between the anode electrode 121g and the cathode electrode 123g due to the plurality of organic light-emitting layers disposed in the vertical direction

R6: Resistance between the first power line PL1 and the contact pad 103

R7: Resistance between the first power line PL1 and the auxiliary electrode AC

Among the above-mentioned resistances, since the hole injection layer, etc., forming the fourth resistance R4 is made of a low-resistance organic light-emitting material, leakage current easily flows through the hole injection layer, etc. When leakage current flows through the hole injection layer, etc., the electrical short between the anode electrode 121g and the cathode electrode 123g may cause light not to be emitted from the corresponding subpixels SPr, SPg, and SPb, or the luminance of the light may be significantly lower than the desired luminance.

In the embodiment, the hole injection layer corresponding to the open structure 105B may be isolated by the open structure 105B, thereby blocking the leakage current flowing through the hole injection layer, etc.

In the embodiment, the cathode electrode 123g may be easily connected to the auxiliary electrode AC through the connection structure 105A, and the deposition area of the organic light-emitting element 120g may be maximized, thereby improving the luminescence efficiency.

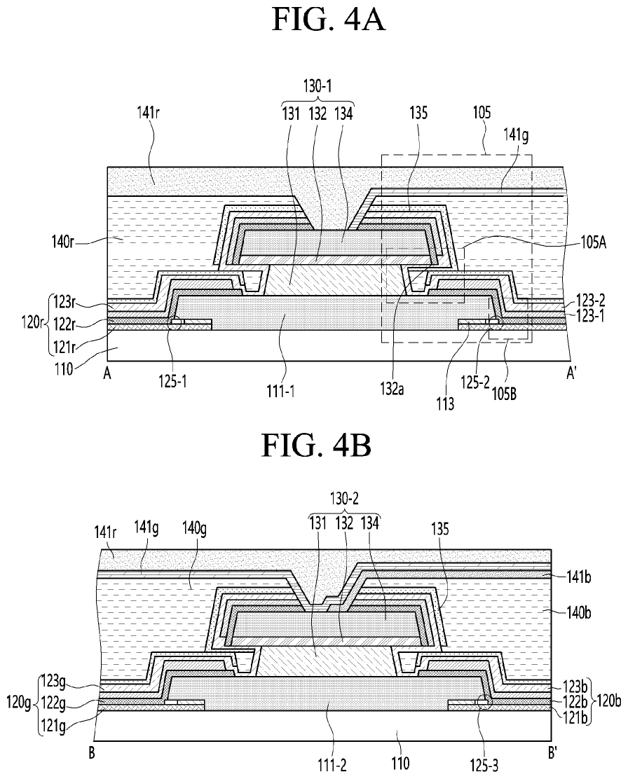

FIG. 4A is a cross-sectional view taken along the line A-A′ in the pixel of FIG. 2. FIG. 4B is a cross-sectional view taken along line B-B′ in the pixel of FIG. 2. FIG. 4C is a cross-sectional view taken along line C-C′ in the pixel of FIG. 2.

Referring to FIG. 1, FIG. 2, and FIG. 4A to FIG. 4C, an organic light-emitting display device according to an embodiment may comprise a plurality of banks 111-1 and 111-2, a plurality of protrusion parts 130-1 and 130-2, a plurality of organic light-emitting elements 120r, 120g, and 120b, etc.

A plurality of banks 111-1 and 111-2, a plurality of protrusion parts 130-1 and 130-2, and a plurality of organic light-emitting elements 120r, 120g, and 120b may be disposed on a substrate 110. A plurality of banks 111-1 and 111-2, a plurality of protrusion parts 130-1 and 130-2, and/or a plurality of organic light-emitting elements 120r, 120g, and 120b may be disposed on the substrate 110 in a stripe shape along the second direction Y, respectively. In this instance, subpixels of the same color may be disposed along the second direction Y. For example, a plurality of red subpixels SPr may be disposed in a stripe shape along the second direction Y. The banks 111-1 and 111-2 may comprise an inorganic material or an organic material. For example, the banks 111-1 and 111-2 may comprise an inorganic material such as SiNx, SiON, etc.

Meanwhile, as illustrated in FIG. 4C, the transverse banks 111-3 may be disposed in a row-line unit along the second direction Y. Alternatively, the protrusion parts may not be disposed in a row-line unit along the second direction Y. That is, the protrusion part along the second direction Y may not be disposed on the transverse bank 111-3.

The first bank 111-1 and the second bank 111-2 may be called longitudinal banks to distinguish them from the transverse bank 111-3.

The plurality of subpixels SPr, SPg, and SPb may be separated from each other by the plurality of banks 111-1 and 111-2. The first bank 111-1 may be disposed between the red subpixel SPr and the green subpixel SPg, and the second bank 111-2 may be disposed between the green subpixel SPg and the blue subpixel SPb. Although not illustrated, the third bank may be disposed between the blue subpixel SPb and another red subpixel SPr.

The plurality of organic light-emitting elements 120r, 120g and 120b may be spatially separated and electrically isolated from each other by the plurality of banks 111-1 and 111-2. Accordingly, the lateral leakage current between the plurality of subpixels SPr, SPg and SPb may be blocked, thereby enhancing color spot and enhancing luminescence efficiency and luminance.

The red organic light-emitting element 120r may be disposed in the red subpixel SPr, the green organic light-emitting element 120g may be disposed in the green subpixel SPg, and the blue organic light-emitting element 120b may be disposed in the blue subpixel SPb.

The plurality of banks 111-1 and 111-2 may have a lattice shape. For example, the banks 111-1 and 111-2 may be disposed along the perimeter of the subpixel SPr, SPg and SPb. That is, the plurality of banks 111-1 and 111-2 may be disposed between the adjacent subpixels SPr, SPg and SPb along the first direction X, and between the adjacent subpixels SPr, SPg and SPb along the second direction Y. In this instance, the adjacent subpixels SPr, SPg and SPb along the first direction X may have different colors, while the adjacent subpixels SPr, SPg and SPb along the second direction Y may have the same color.

The plurality of organic light-emitting elements 120r, 120g and 120b may be separated from each other by the plurality of banks 111-1 and 111-2. The plurality of banks 111-1 and 111-2 may be disposed to distinguish the plurality of organic light-emitting elements 120r, 120g and 120b, respectively. The red organic light-emitting element 120r and the green organic light-emitting element 120g may be separated by the first bank 111-1, and the green organic light-emitting element 120g and the blue organic light-emitting element 120b may be separated by the second bank 111-2.

Meanwhile, the organic light-emitting display device according to the embodiment may comprise an open structure 105B in an edge region of each of the plurality of banks 111-1 and 111-2. For example, the open structure 105B may be disposed in an edge region of the lower side of each of the plurality of banks 111-1 and 111-2, but is not limited thereto.

The open structure 105B may be disposed in an edge region of the banks 111-1 and 111-2 between the subpixels SPr, SPg, and SPb along the first direction X. The open structure 105B may be disposed in the edge region of the banks 111-1 and 111-2 between the subpixels SPr, SPg, and SPb along the second direction Y.

When the organic light-emitting elements 120r, 120g, and 120b are deposited on the banks 111-1 and 111-2, some layers of the organic light-emitting elements 120r, 120g, and 120b may be isolated by the open structure 105B. For example, the open structure 105B may isolate the low-resistance layers of each of the organic light-emitting elements 120r, 120g, and 120b. The low-resistance layers may comprise, for example, a hole injection layer, a charge generation layer, etc. The low-resistance layer may mean a layer having a resistance value lower than the resistance value of a high-resistance layer, for example, an organic light-emitting layer, an electron transport layer, an electron injection layer, etc.

For example, the organic light-emitting layers 122r, 122g and 122b of the organic light-emitting elements 120r, 120g and 120b may have separation structures 125-1 to 125-3 corresponding to the open structure 105B. The separation structures 125-1 to 125-3 may mean a shape in which some layers of the organic light-emitting layers 122r, 122g and 122b are isolated. Accordingly, in the separation structures 125-1 to 125-3, for example, a hole injection layer, a charge generation layer, etc. may be isolated.

The open structure 105B may comprise at least one or more blocking layer 113 which is inwardly recessed from the side portion of the banks 111-1 and 111-2. An undercut structure may be formed in the edge regions of the banks 111-1 and 111-2 by the blocking layer 113. The blocking layer 113 may comprise, but is not limited to, a silicon-based inorganic material, aluminum (Al), molybdenum (Mo), a molybdenum alloy, etc.

When organic light-emitting elements 120r, 120g and 120b are deposited on banks 111-1 and 111-2 where the undercut structure is formed in this way, some layers corresponding to the undercut structure, such as the hole injection layer, the charge generation layer, etc., among the organic light-emitting layers 122r, 122g, and 122b of the organic light-emitting elements 120r, 120g, and 120b, may be isolated.

Meanwhile, as described above, organic light-emitting elements 120r, 120g, and 120b corresponding to the subpixels SPr, SPg, and SPb may be disposed, respectively.

The red organic light-emitting element 120r may comprise an anode electrode 121r, a red organic light-emitting layer 122r, a cathode electrode 123r, etc. The red organic light-emitting layer 122r may be disposed on the anode electrode 121r, and the cathode electrode 123r may be disposed on the red organic light-emitting layer 122r. The green organic light-emitting element 120g may comprise an anode electrode 121g, a green organic light-emitting layer 122g, a cathode electrode 123g, etc. The green organic light-emitting layer 122g may be disposed on the anode electrode 121g, and the cathode electrode 123g may be disposed on the green organic light-emitting layer 122g. The blue organic light-emitting element 120b may comprise an anode electrode 121b, a blue organic light-emitting layer 122b, a cathode electrode 123b, etc. The blue organic light-emitting layer 122b may be disposed on the anode electrode 121b, and the cathode electrode 123b may be disposed on the blue organic light-emitting layer 122b.

The anode electrodes 121r, 121g, and 121b may comprise a plurality of conductive layers. The anode electrodes 121r, 121g, and 121b may have a triple structure composed of ITO/Ag alloy/ITO. The anode electrodes 121r, 121g, and 121b may have a triple structure composed of ITO/Ag alloy/(Ti, Mo, or MoTi).

One end of the anode electrode 121r, 121g and 121b may be disposed below the banks 111-1 and 111-2. That is, one end of the bank 111-1 and 111-2 may be disposed on one end of the anode electrode 121r, 121g and 121b. One end of the anode electrode 121r, 121g and 121b may vertically overlap with the banks 111-1 and 111-2.

The red organic light-emitting layer 122r, the green organic light-emitting layer 122g and the blue organic light-emitting layer 122b may comprise at least a hole injection layer comprising a low-resistance organic light-emitting material, respectively.

Meanwhile, one end of the hole injection layer and/or the charge generation layer may be in contact with the cathode electrode 123r, 123g, and 123b. In addition, the lower surface of the hole injection layer may be in contact with the anode electrode 121r, 121g, and 121b. In this instance, since the resistance of the hole injection layer is small, a leakage current may flow between the anode electrode 121r, 121g, and 121b and the cathode electrode 123r, 123g, and 123b, and an electrical short may occur between the anode electrode 121r, 121g, and 121b and the cathode electrode 123r, 123g, and 123b.

However, according to an embodiment, since the hole injection layer and/or the charge generation layer are isolated by the open structure 105B disposed in the edge region of the bank 111-1 and 111-2, the anode electrode 121r, 121g and 121b and the cathode electrode 123r, 123g and 123b may be electrically disconnected, so that an electrical short may be prevented.

Meanwhile, the organic light-emitting display device according to the embodiment may comprise a plurality of protrusion parts 130-1 and 130-2.

The plurality of organic light-emitting elements 120r, 120g and 120b may be spatially separated and electrically isolated from each other by the plurality of protrusion parts 130-1 and 130-2. Accordingly, the lateral leakage current between the plurality of subpixels SPr, SPg and SPb may be blocked, so that color spot may be enhanced and the luminescence efficiency and luminance may be enhanced.

The plurality of protrusion parts 130-1 and 130-2 may be disposed on the upper side of the plurality of banks 111-1 and 111-2. The first protrusion part 130-1 may be disposed on the upper side of the first bank 111-1 between the red subpixel SPr and the green subpixel SPg. The second protrusion part 130-2 may be disposed on the upper side of the second bank 111-2 between the green subpixel SPg and the blue subpixel SPb.

The left side portion and right side portion of the protrusion part 130-1 and 130-2 may have shapes that are symmetrical with respect to the center normal of the protrusion part 130-1 and 130-2, but is not limited thereto. For example, the left side portion and right side portion of the protrusion part 130-1 and 130-2 may each have an undercut structure. In this instance, the undercut structure on the left side portion and the undercut structure on the right side portion may have shapes that are symmetrical with respect to the center normal of the protrusion part 130-1 and 130-2.

The protrusion part 130-1 and 130-2 may have a connection structure 105A comprising an auxiliary electrode AC that is electrically connected to the cathode electrode 123r, 123g, and 123b.

The protrusion part 130-1 and 130-2 may comprise the first layer 131 and the second layer 132 on the first layer 131.

The side portion of the first layer 131 may be recessed into the inside of the protrusion part from the side portion of the second layer 132. Accordingly, an undercut structure may be formed on the side portion of the protrusion part by the first layer 131 and the second layer 132. The undercut structure may have a cave shape. For example, the undercut structure may have a U-cave shape. Accordingly, the undercut structure may be called a cave, a U-cave, a cave portion, etc. In order to form the undercut structure, the first layer 131 and the second layer 132 may have different etching selectivity. For example, the first layer 131 may comprise a material having a high etching rate, and the second layer 132 may comprise a material having a low etching rate. Accordingly, when the first layer 131 and the second layer 132 are etched after the photosensitive pattern is formed on the second layer 132, the side portion of the first layer 131 is etched faster than the side portion of the second layer 132, so that an undercut structure may be formed on the side portion of the protrusion part 130-1 and 130-2.

At least one of the first layer 131 or the second layer 132 may comprise a metal or a conductive oxide material having excellent electrical conductivity. As the metal, titanium (Ti), molybdenum (Mo), molybdenum-titanium (MoTi), aluminum (Al), copper (Cu), an alloy thereof, etc. may be used. As the conductive oxide material, ITO, IZO, etc. may be used.

Meanwhile, by adjusting the target-source distance of the evaporation source (or the evaporation source device), the deposition material may be deposited on the substrate 110 at different deposition angles. The target-source distance may be the distance between the evaporation source and the substrate 110. The deposition angle may be the angle of a virtual line between the evaporation source and the lower edge 132a of the second layer 132 with respect to the normal direction. For example, the greater the target-source distance, the smaller the deposition angle can be. The smaller the deposition angle, the closer the layer formed by the deposition material can be deposited to the adjacent subpixel. The larger the deposition angle, the closer the corresponding layer can be deposited to the protrusion part 130-1 and 130-2.

As illustrated in FIGS. 4A, 4B, and 4C, since the deposition materials are deposited at different deposition angles, one end of the organic light-emitting layer 122r, 122g, and 122b and one end of the first conductive layer 123-1 of the cathode electrode 123r, 123g, and 123b may be positioned differently from each other.

The cathode electrode 123r, 123g and 123b may comprise a plurality of conductive layers 123-1 and 123-2. For example, the cathode electrode 123r, 123g and 123b may comprise a first conductive layer 123-1 and a second conductive layer 123-2 on the first conductive layer 123-1, but three or more conductive layers may be included.

One end of the organic light-emitting layer 122r, 122g and 122b and one end of the first conductive layer 123-1 may be positioned on the upper side of the bank 111-1 and 111-2. For example, one end of the organic light-emitting layer 122r, 122g, and 122b may be positioned closer to the first layer 131 than one end of the first conductive layer 123-1.

The second conductive layer 123-2 may be disposed on the entire region of the substrate 110. The second conductive layer 123-2 may be deposited by using a sputtering process. That is, the second conductive layer 123-2 may be disposed on the upper side of the first conductive layer 123-1 of each of the subpixels SPr, SPg, and SPb, the upper side of the bank 111-1 and 111-2, and the side portion and upper side of the protrusion part 130-1 and 130-2. The second conductive layer 123-2 may be in contact with the side portion of the first layer 131 and/or the lower side of the second layer 132.

For example, the first conductive layer 123-1 may comprise a metal having excellent electrical conductivity, and the second conductive layer 123-2 may comprise a conductive oxide material. For example, the first conductive layer 123-1 may comprise a Mg:Ag alloy, and the second conductive layer 123-2 may comprise ITO, IZO, etc.

The Mg:Ag alloy may be formed as the first conductive layer 123-1 through deposition by using an evaporation source. However, since the step coverage characteristics of Mg:Ag are not good, it is difficult for the deposition material comprising the Mg:Ag alloy to be deposited deep inside the undercut structure of the connection structure 105A. In addition, when the uniformity of the film thickness of the first conductive layer 123-1 comprising the Mg:Ag alloy is insufficient or the process margin is insufficient, the first conductive layer 123-1 may not be electrically connected to the auxiliary electrode AC included in the connection structure 105A, resulting in poor electrical connection.

To solve this problem, a conductive oxide material such as ITO having excellent step coverage characteristics may be deposited on the substrate 110 using a sputtering process, so that it can be deposited deep inside the undercut structure of the connection structure 105A. Accordingly, the second conductive layer 123-2 may be stably deposited on the side portion of the first layer 131, which is the auxiliary electrode AC, so that electrical connection failure between the auxiliary electrode AC and the cathode electrode 123r, 123g, and 123b comprising the first conductive layer 123-1 and the second conductive layer 123-2 can be prevented. In addition, since the uniformity of the film thickness of the conductive layer is secured, the stability of the production quality can be improved.

When the second conductive layer 123-2 is formed on the first conductive layer 123-1, there is no need to adjust or manage the deposition angle to deposit the first conductive layer 123-1 using an evaporation source. In addition, even if the organic light-emitting layers 122r, 122g and 122b using an evaporation source as well as the first conductive layer 123-1 are freely deposited regardless of the deposition angle, the organic light-emitting layers 122r, 122g and 122b can be deposited on the corresponding subpixels SPr, SPg and SPb, and the cathode electrodes 123r, 123g and 123b may be stably connected to the auxiliary electrodes AC of the protrusion parts 130-1 and 130-2 by the second conductive layer 123-2. Therefore, when configured with a combination of the aforementioned connection structure 105A and the open structure 105B, productivity and material utilization efficiency can be improved through a more free deposition process.

In addition, when the organic light-emitting display device is implemented in a top-emission manner, the luminescence efficiency can be improved by utilizing constructive interference between the anode electrode 121r, 121g and 121b and the cathode electrode 123r, 123g and 123b, by using the cathode electrode 123r, 123g and 123b comprising the first conductive layer 123-1 comprising the Ag:Mg alloy and the anode electrode 121r, 121g and 121b comprising the transflective material.

Meanwhile, the protrusion parts 130-1 and 130-2 may comprise a fourth layer 134 on the second layer 132. The fourth layer 134 may be omitted. The fourth layer 134 may comprise an inorganic material such as SiO₂, SiNx, SiONx. The fourth layer 134 may comprise a conductive oxide material such as ITO. The fourth layer 134 may act as a stopper for the second layer 132. As described above, in order to form a side-by-side structure, the red subpixel SPr, the green subpixel SPg, and the blue subpixel SPb may be etched twice, respectively. At this time, when these two etchings are performed, the area or thickness of the second layer 132 may be changed. In this instance, there is a problem that the deposition angle determined by the edge 132a on the lower side of the second layer 132 is different, so that the deposition area in each subpixel SPr, SPg, and SPb are different, resulting in a decrease in image quality.

In order to solve the above-mentioned problem, when a fourth layer 134 acting as a stopper is formed on the second layer 132, even if two etchings are performed, the etching of the second layer 132 may be suppressed or prevented by the fourth layer 134, so that the deposition angle determined by the edge 132a on the lower side of the second layer 132 may be fixed. Accordingly, the deposition area in each of the subpixels SPr, SPg, and SPb may be secured as the target area, so that the image quality can be improved.

Although not illustrated, the third layer may be disposed below the first layer 131, but is not limited thereto. The third layer may comprise a material having a low etching rate. The third layer may comprise a metal or a conductive oxide material having excellent electrical conductivity. The third layer may comprise an inorganic material having an etching rate.

When the third layer comprises a metal or a conductive oxide material, the third layer may be an auxiliary electrode AC.

The etching rate of the third layer may be the same as or slower than the etching rate of the second layer 132. When the second layer 132 and the third layer are etched simultaneously, since the etching rate of the third layer is the same as or slower than the etching rate of the second layer 132, the side portion of the third layer may be positioned on the same vertical line as the side portion of the second layer 132 or may be disposed to extend further in the direction of the adjacent subpixel from the side portion of the second layer 132.

Meanwhile, the organic light-emitting display device according to the embodiment may comprise an encapsulation layer 135. The encapsulation layer 135 may be a blocking layer that prevents moisture, etc. from penetrating into the organic light-emitting element 120r, 120g, and 120b.

Meanwhile, the organic light-emitting display device according to the embodiment may comprise a plurality of color filter layers 140r, 140g, and 140b and a plurality of encapsulation layers 141r, 141g, and 141b.

The plurality of color filter layers 140r, 140g, and 140b may each comprise a resin material. The plurality of encapsulating layers 141r, 141g, and 141b may each comprise a plurality of layers. Some of the plurality of layers may each comprise an inorganic material, and other layers may each comprise an organic material.

The red color filter layer 140r may be disposed in the red subpixel SPr. The red color filter layer 140r may be disposed on the red organic light-emitting element 120r in the red subpixel SPr, so that only red light corresponding to a target red wavelength band set for the red color filter layer 140r among the wavelength band of red light emitted from the red organic light-emitting element 120r may be emitted.

The green color filter layer 140g may be disposed in the green subpixel SPg. The green color filter layer 140g may disposed on the green organic light-emitting element 120g in the green subpixel SPg, so that only green light corresponding to a target green wavelength band set for the green color filter layer 140g may be emitted among the wavelength band of green light emitted from the green organic light-emitting element 120g.

The blue color filter layer 140b may be disposed on the blue subpixel SPb. The blue color filter layer 140b may be disposed on the blue organic light-emitting element 120b in the blue subpixel SPb, so that only blue light corresponding to a target blue wavelength band set for the blue color filter layer may be emitted among the wavelength band of blue light emitted from the blue organic light-emitting element 120b.

The plurality of color filter layers 140r, 140g, and 140b may each have a color filter function that allows only color light of a preset wavelength band to be emitted.

As described above, the plurality of color filter layers 140r, 140g and 140b may further enhance the color purity of each color compared to when there is no color filter layer, and especially may play a role in enhancing the change in color purity according to the viewing angle in an organic light-emitting display device having a top emission structure. Currently, a polarizing plate may be attached to remove light reflected by the reflective material of the anode electrode 121r, 121g and 121b when external light is incident, but the most important role of the plurality of color filter layers 140r, 140g and 140b may be that the plurality of color filter layers 140r, 140g and 140b may absorb external light to improve the contrast ratio, and further, contribute to cost reduction by removing the polarizing plate.

Meanwhile, the plurality of color filter layers 140r, 140g, and 140b may have a function of a photosensitive pattern for forming a pattern of the encapsulation layer 135, the cathode electrode 123r, 123g, and 123b, and the organic light-emitting layer 122r, 122g, and 122b, respectively.

As illustrated in FIG. 4A, the encapsulation layer 135, the cathode electrode 123r, and the red organic light-emitting layer 122r may be etched using the red color filter layer 140r, so that they may be formed only in the red subpixel SPr. In this instance, one end of the encapsulation layer 135, one end of the cathode electrode 123r, and one end of the red organic light-emitting layer 122r on the first protrusion part 130-1 may be positioned on the same vertical line or diagonal line.

As illustrated in FIG. 4B, the encapsulation layer 135, the cathode electrode 123g, and the green organic light-emitting layer 122g may be etched using the green color filter layer 140g, so that they may be formed only in the green subpixel SPg. In this instance, one end of the encapsulation layer 135, one end of the cathode electrode 123g, and one end of the green organic light-emitting layer 122g on the first protrusion part 130-1 may be positioned on the same vertical line or diagonal line.

As illustrated in FIG. 4C, the encapsulation layer 135, the cathode electrode 123b, and the blue organic light-emitting layer 122b may be etched using the blue color filter layer 140b, so that they may be formed only the blue subpixel SPb. In this instance, one end of the encapsulation layer 135, one end of the cathode electrode 123b, and one end of the blue organic light-emitting layer 122b on the first protrusion part 130-1 may be positioned on the same vertical line or diagonal line.

As an example, the blue organic light-emitting element 120b, the green organic light-emitting element 120g, and the red organic light-emitting element 120r may be formed in that order, but is not limited thereto.

Meanwhile, the encapsulation layers 141r, 141g, and 141b may comprise a plurality of layers comprising organic materials or inorganic materials.

The encapsulation layers 141r, 141g, and 141b may protect the plurality of color filter layers 140r, 140g, and 140b made of a resin material from being etched. For example, when a blue encapsulation layer 141b is formed on a blue color filter layer 140b used for patterning a blue organic light-emitting element 120b, the blue encapsulation layer 141b may prevent the etching of the blue color filter layer 140b while the green organic light-emitting element 120g is etched. Similarly, when a green encapsulation layer 141g is formed on a green color filter layer 140g used for patterning a green organic light-emitting element 120g, the green encapsulation layer 141g may prevent the etching of the green color filter layer 140g while the red organic light-emitting element 120r is etched. Therefore, the red encapsulation layer 141r, the green encapsulation layer 141g, and the blue encapsulation layer 141b may serve as stoppers for preventing etching.

Meanwhile, the plurality of color filter layers 140r, 140g, and 140b may each comprise a light scattering agent or a light diffusing agent. Light may be scattered or diffused by the light scattering agent or the light diffusing agent, thereby improving luminescence efficiency.

Meanwhile, the red encapsulating layer 141r, the green encapsulating layer 141g, and the blue encapsulating layer 141b may each comprise a plurality of layers comprising an inorganic material and an organic material.

The red encapsulating layer 141r may be disposed on the red color filter layer 140r, the green encapsulating layer 141g may be disposed on the green color filter layer 140g, and the blue encapsulating layer 141b may be disposed on the blue color filter layer 140b.

The red encapsulation layer 141r, the green encapsulation layer 141g, and the blue encapsulation layer 141b may each comprise at least one or more layer. For example, the red encapsulation layer 141r, the green encapsulation layer 141g, and the blue encapsulation layer 141b may each comprise a first inorganic layer, an organic layer on the first inorganic layer, a second inorganic layer on the organic layer, etc., but are not limited thereto. The first inorganic layer and the second inorganic layer may comprise an inorganic material such as SiNx, and the organic layer may comprise a resin material, but are not limited thereto.

According to an embodiment, a plurality of subpixels SPr, SPg, and SPb may be sequentially formed to manufacture an organic light-emitting display device having a side-by-side structure. For example, a blue organic light-emitting element 120b, a blue color filter layer 140b, and a blue encapsulation layer 141b may be formed and patterned over the entire region of the substrate 110 using a photolithography process, so that a blue subpixel SPb may be formed. Thereafter, a green organic light-emitting element 120g, a green color filter layer 140g, and a green encapsulation layer 141g may be formed and patterned over the entire region of the substrate 110 using a photolithography process, so that a green subpixel SPg may be formed. Thereafter, a red organic light-emitting element 120r, a red color filter layer 140r, and a red encapsulation layer 141r may be formed and patterned over the entire region of the substrate 110 using a photolithography process, so that a red subpixel SPr may be formed.

Meanwhile, in the first embodiment (FIGS. 1 and 2), the red organic light-emitting element 120r, the green organic light-emitting element 120g, and the blue organic light-emitting element 120b may be disposed in a stripe shape along the second direction Y.

In contrast, although not illustrated, the red organic light-emitting element 120r, the green organic light-emitting element 120g, and the blue organic light-emitting element 120b may be disposed in a dot shape and spaced apart from each other. The red organic light-emitting element 120r may be disposed in the red subpixel SPr, the green organic light-emitting element 120g may be disposed in the green subpixel SPg, and the blue organic light-emitting element 120b may be disposed in the blue subpixel SPb. One pixel P may be configured by the red subpixel SPr, the green subpixel SPg, and the blue subpixel SPb.

For example, the red organic light-emitting element 120r and the green organic light-emitting element 120g may be isolated by one row line along the second direction Y, respectively. For example, the blue organic light-emitting element 120b may be isolated by two row lines along the second direction Y.

For example, the area of the blue organic light-emitting element 120b may be greater than the area of the red organic light-emitting element 120r or the area of the green organic light-emitting element 120g. The length of the blue organic light-emitting element 120b in the second direction Y may be similar to the sum of the width of the red organic light-emitting element 120r and the width of the green organic light-emitting element 120g, but is not limited thereto.

In a pixel structure in which the red organic light-emitting element 120r, the green organic light-emitting element 120g, and the blue organic light-emitting element 120b are spaced apart from each other in a dot shape, there is no connection structure (105A of FIG. 4A) between adjacent subpixels along the first direction X, but an asymmetric open-connection structure 105, that is, a connection structure 105A and an open structure 105B, may be provided at least two or more edges of each of the subpixels SPr, SPg, and SPb along the second direction Y.

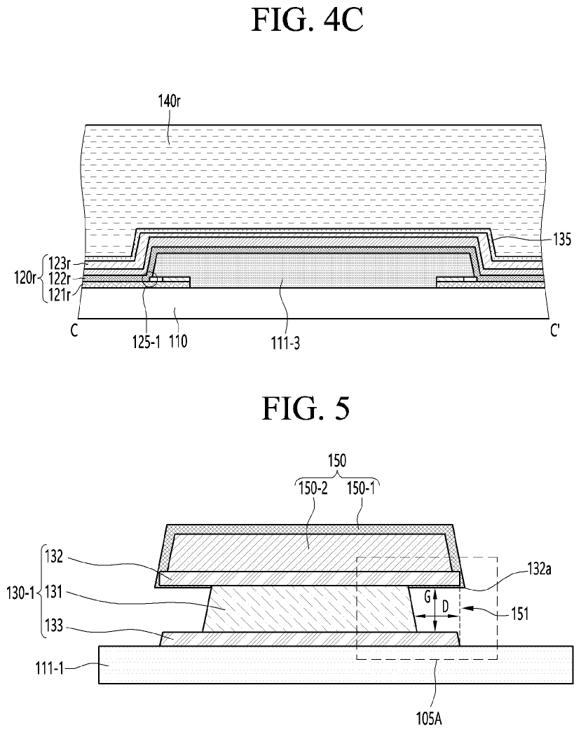

FIG. 5 is a cross-sectional view illustrating an organic light-emitting display device according to the first embodiment. FIG. 5 illustrates the first bank 111-1 and the first protrusion part 130-1 in FIGS. 4A to 4C, but the second bank 111-2 may also have the same structure or shape as the first bank 111-1 illustrated in FIG. 5. The remaining components not illustrated in FIG. 5 may also be illustrated in FIG. 5 in the same manner as the corresponding components illustrated in FIGS. 4A to 4C.

Referring to FIGS. 4A to 4C and FIG. 5, the organic light-emitting display device according to the first embodiment may comprise a first bank 111-1, a first protrusion part 130-1, etc.

Since the first bank 111-1 and the first protrusion part 130-1 have been described in FIG. 4A to 4C, a detailed description thereof will be omitted.

The first protrusion part 130-1 may comprise an etch-stop layer 150. The etch-stop layer 150 may not be included in the first protrusion part 130-1. That is, the etch-stop layer 150 may be separately provided on the upper side of the first protrusion part 130-1.

When manufacturing an organic light-emitting display device having a side-by-side structure using a photolithography process, the size or shape of the first protrusion part 130-1 may change while two etching processes are performed for each subpixel SPr, SPg, and SPb, which may affect the image quality of the product. The etch-stop layer 150 may play a role in preventing the image quality of the product from being affected by ensuring that the size or shape of the first protrusion part 130-1 remains unchanged even when two etching processes are performed.

Specifically, an organic deposition material for forming the organic light-emitting layer 122r and 122g, a deposition material for forming the cathode electrode 123r and 123g, and an organic or inorganic material for forming the encapsulation layer 135 may be formed through a dry etching process by using a gas such as CF₄, SF₆, O₂, Cl₂, etc. While these materials are dry etched, the first protrusion part 130-1 may also be etched, so that the size or shape of the first protrusion part 130-1 may be changed.

When the size or shape of the first protrusion part 130-1 is changed, the open depth D or the open gap G of the undercut structure 151 of the connection structure 105A may be changed, which may affect the connection resistance (or contact resistance) between the auxiliary electrode AC and the cathode electrode 123g. Accordingly, difference in the characteristics of the organic light-emitting elements 120r, 120g, and 120b of the subpixels SPr, SPg, and SPb may occur, resulting in poor image quality, such as stains and color spots.

To solve this problem, an etch-stop layer 150 may be formed on the uppermost side of the first protrusion part 130-1. The etch-stop layer 150 may protect the first protrusion part 130-1 from being etched by an etching gas, such as CF₄, during an etching process, so that the size or shape of the first protrusion part 130-1 may not be changed. Accordingly, the open depth D or the open gap G of the undercut structure 151 of the connection structure 105A may be maintained as is, so that difference in the characteristics of the organic light-emitting elements 120r, 120g, and 120b of the subpixels SPr, SPg, and SPb can be eliminated, thereby preventing poor image quality.

Referring again to FIG. 5, the first protrusion part 130-1 may have a connection structure 105A comprising an auxiliary electrode AC electrically connected to the cathode electrode 123g. In this instance, the etch-stop layer 150 may be disposed on the connection structure 105A.

The first protrusion part 130-1 may comprise a first layer 131 on the first bank 111-1, a second layer 132 on the first layer 131, and a third layer 133 below the first layer 131. The third layer 133 may be omitted. At least one or more of the first layer 131, the second layer 132, or the third layer 133 may be an auxiliary electrode AC.

The first layer 131, the second layer 132, and the third layer 133 may have different etch selectivity from each other. For example, the etching rate of the first layer 131 may be greater than the etching rate of the second layer 132 or the third layer 133. When the first layer 131, the second layer 132, and the third layer 133 are etched, the side portion of the first layer 131 may be etched the fastest, thereby forming the undercut structure 151. That is, the side portion of the first layer 131 may be recessed into the inside of the first protrusion part 130-1 from the side portion of the second layer, thereby forming the undercut structure 151. The side portion of the third layer 133 may be positioned on the same vertical line or diagonal line as the side portion of the second layer 132, or may extend in the direction of the subpixel SPg from the side portion of the second layer 132.

The etch-stop layer 150 may comprise a material that is not etched by an etching gas, such as CF₄. For example, the etch-stop layer 150 may comprise a conductive oxide material such as ITO. For example, the etch-stop layer 150 may comprise an insulating material such as Al₂O₃. For example, the etch-stop layer 150 may comprise a metal such as copper (Cu). For example, the etch-stop layer 150 may comprise a metal oxide material such as CuOx.

The etch-stop layer 150 may be disposed on the connection structure 105A. For example, the etch-stop layer 150 may be disposed on the second layer 132 of the first protrusion part 130-1.

The lower edge 132a of the second layer 132 is an important region that determines the deposition angle at which various deposition materials constituting the organic light-emitting element 120g are sprayed onto the substrate 110. Accordingly, when the lower edge 132a of the second layer 132 is etched by an etching gas such as CF₄, the size or shape of the first protrusion part 130-1 may change. When the lower edge 132a of the second layer 132 is etched, various deposition materials may be sprayed onto the substrate 110 at a deposition angle different from the target deposition angle. Accordingly, the image quality defect as described above may occur.

Referring again to FIG. 5, the etch-stop layer 150 may surround the second layer 132 of the first protrusion part 130-1. For example, the etch-stop layer 150 may be disposed on the side portion and lower side of the second layer 132. Therefore, since the lower edge 132a of the second layer 132 is not exposed by the etch-stop layer 150, the lower edge 132a of the second layer 132 may not be etched by an etching gas such as CF₄.

The etch-stop layer 150 may comprise the first etch-stop layer 150-1 and the second etch-stop layer 150-2.

The second etch-stop layer 150-2 may be omitted. The second etch-stop layer 150-2 may be the fourth layer 134 illustrated in FIGS. 4A and 4B, but is not limited thereto.

The first etch-stop layer 150-1 may be disposed on the second layer 132 of the first protrusion part 130-1, and the second etch-stop layer 150-2 may be disposed between the second layer 132 and the first etch-stop layer 150-1. The first etch-stop layer 150-1 may be disposed on the second etch-stop layer 150-2.

The first etch-stop layer 150-1 may surround not only the second layer 132 of the first protrusion part 130-1, but also the second etch-stop layer 150-2. In this instance, the first etch-stop layer 150-1 may be disposed on the lower side of the second layer 132 of the first protrusion part 130-1 via the side portion of the second etch-stop layer 150-2.

For example, the first etch-stop layer 150-1 may comprise a conductive oxide material such as ITO, and the second etch-stop layer 150-2 may comprise an insulating material such as Al₂O₃, but is not limited thereto.

According to an embodiment, since the etch-stop layer 150 is disposed on the first protrusion part 130-1, when an organic light-emitting display device having a side-by-side structure is manufactured using a photolithography process, even if two etching processes are performed for each of the subpixels SPr, SPg, and SPb, the first protrusion part 130-1 may not be etched by the etch-stop layer 150. Accordingly, the difference in characteristics of the organic light-emitting elements 120r, 120g, and 120b for the subpixels SPr, SPg, and SPb may be eliminated, thereby preventing poor image quality.

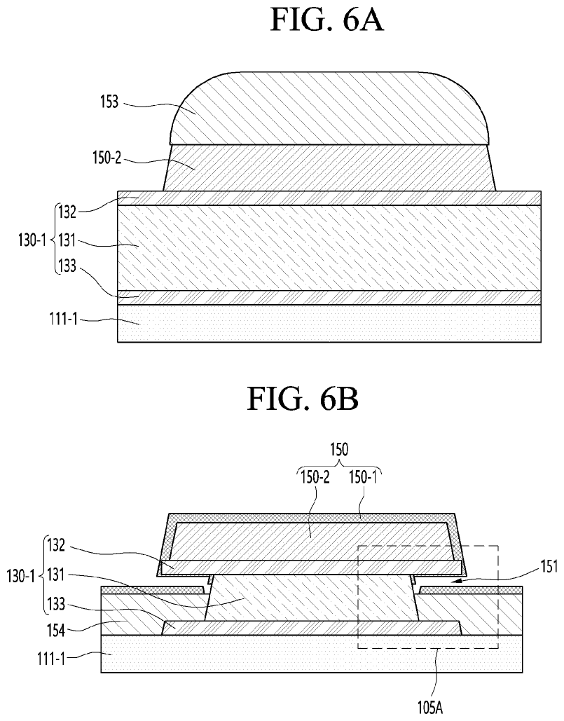

FIGS. 6A to 6C illustrate a manufacturing process of an organic light-emitting display device according to the first embodiment.

As illustrated in FIGS. 4A to 4C and FIG. 6A, a third layer 133, a first layer 131, and a second layer 132 may be formed on the first bank 111-1. The first layer 131, the second layer 132, and the third layer 133 may have different etching selectivity.

An insulating film and a photosensitive film may be formed on the second layer 132, and an etching process may be performed on the insulating film using a patterned photosensitive pattern 153 of the photosensitive film, thereby forming a second etch-stop layer 150-2.

As illustrated in FIGS. 4A to 4C and 6B, an etching process may be performed on the third layer, the first layer 131 and the second layer 132 using the photosensitive pattern 153, so that a connection structure 105A having an undercut structure 151 may be formed.

Thereafter, the photosensitive pattern 153 may be removed.

Thereafter, a photosensitive pattern 154 may be formed on the remaining region of the substrate 110 excluding the second etch-stop layer 150-2.

Thereafter, a conductive oxide film may be deposited on the substrate 110. The conductive oxide film may be deposited on the second etch-stop layer 150-2 and the photosensitive pattern 154.

As illustrated in FIGS. 4A to 4C and FIG. 6C, the photosensitive pattern 154 on which the conductive oxide film is deposited is removed, so that the conductive oxide film may be formed on the second etch-stop layer 150-2 as the first etch-stop layer 150-1. The etch-stop layer 150 may be formed by the first etch-stop layer 150-1 and the second etch-stop layer 150-2.

In contrast, the second etch-stop layer 150-2 may be omitted by omitting the process illustrated in FIG. 6A. Thereafter, by performing the process illustrated in FIGS. 6B and 6C, the etch-stop layer 150 may comprise only the first etch-stop layer 150-1 as a single layer.

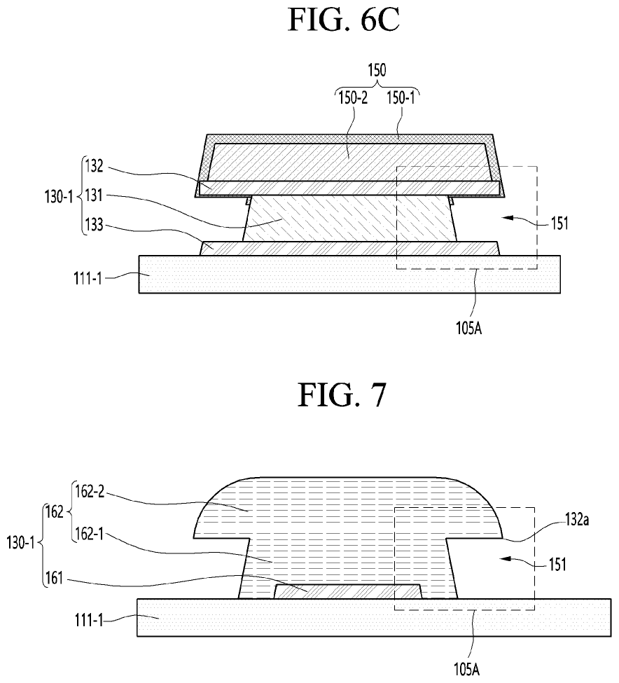

FIG. 7 is a cross-sectional view illustrating an organic light-emitting display device according to a second embodiment. Although FIG. 5 illustrates the first bank 111-1 in FIGS. 4A to 4C, the second bank 111-2 may also have the same structure or shape as the first bank 111-1 illustrated in FIG. 5. The remaining components not illustrated in FIG. 5 may also be illustrated in FIG. 5 in the same manner as the corresponding components illustrated in FIGS. 4A to 4C.

Referring to FIGS. 4A to 4C and FIG. 7, the organic light-emitting display device according to the second embodiment may comprise a first bank 111-1, a first protrusion part 130-1, etc.

The first bank 111-1 and the first protrusion part 130-1 have been described in FIGS. 4A to 4C, so that detailed descriptions thereof are omitted.

The first protrusion part 130-1 may comprise a plating layer 162. The plating layer 162 itself may be an etch-stop layer 150.

A seed layer 161 may be provided for forming the plating layer 162. Accordingly, the first protrusion part 130-1 may comprise the seed layer 161 and the plating layer 162.

In an embodiment, the first protrusion part 130-1 may comprise a connection structure 105A and an etch-stop layer 150. That is, the first protrusion part 130-1 may comprise a connection structure 105A having an undercut structure 151 and an etch-stop layer 150 on the connection structure 105A. At this time, the undercut structure 151 and the etch-stop layer 150 may be integrally formed by the plating layer 162.

The seed layer 161 may comprise a metal that facilitates the formation of the plating layer 162. The plating layer 162 may comprise a metal such as copper (Cu).

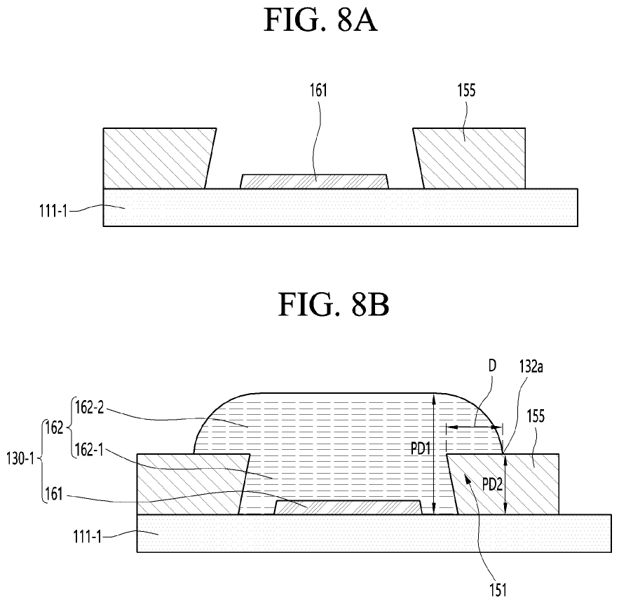

As will be described later, after the seed layer 161 is formed on the first bank 111-1, a photosensitive pattern (155 of FIG. 8A) may be formed in the remaining region except for the region where the plating layer 162 is to be formed. The photosensitive pattern 155 may have a shape corresponding to the undercut structure 151. Thereafter, a plating process is performed by using the photosensitive pattern 155, so that a connection structure 105A of the undercut structure 151 may be formed. Thereafter, if the plating process is continuously performed, a plating layer 162 may be formed on the upper surface of the photosensitive pattern 155, and the plating layer 162 formed on the upper surface of the photosensitive pattern 155 may become an etch-stop layer 150. Various undercut structures 151 may be formed depending on the shape of the photosensitive pattern 155. In addition, by adjusting the distance between the photosensitive pattern 155 and the seed layer 161 or the thickness of the photosensitive pattern 155, an undercut structure 151 having various open depths D and open gaps G may be formed.

The plating layer 162 may comprise a lower region 162-1 and an upper region 162-2. An undercut structure 151 of the connection structure 105A may be formed by the lower region 162-1 and the upper region.

In the plating layer 162, the width of the upper region 162-2 may be greater than the width of the lower region 162-1. The plating layer 162 may have a rounded-shape mushroom structure at the edge of the surface of the upper region 162-2. By the rounded-shape mushroom structure, the uniformity of the film thickness of the deposition material deposited on the plating layer 162, and the homogeneity of the film quality, etc. may be secured.

According to an embodiment, since the plating layer 162 comprising the connection structure 105A and the etch-stop layer 150 is provided, when manufacturing an organic light-emitting display device having a side-by-side structure by using a photolithography process, even if two etching processes are performed for each of the subpixels SPr, SPg, and SPb, the first protrusion part 130-1 may not be etched by the etch-stop layer 150. Accordingly, the difference in characteristics of the organic light-emitting elements 120r, 120g, and 120b for the subpixels SPr, SPg, and SPb may be eliminated, thereby preventing poor image quality.

According to the embodiment, since there is no need to form an undercut structure 151 through deposition and etching of the first layer 131, the second layer 132, and the third layer 133 as illustrated in FIG. 5, the process may be greatly simplified, and since an undercut structure 151 having an accurate and continuous open depth D and open gap G is secured, the difference in characteristics of the organic light-emitting elements 120r, 120g, and 120b for the subpixels SPr, SPg, and SPb may be eliminated, thereby preventing poor image quality.

FIGS. 8A to 8C illustrate a manufacturing process of an organic light-emitting display device according to the second embodiment.

As illustrated in FIGS. 4A to 4C and FIG. 8A, a seed layer 161 may be formed on the first bank 111-1. The seed layer 161 may comprise a metal.

Thereafter, the photosensitive pattern 155 may be formed on the first bank 111-1. The photosensitive pattern 155 may not be formed on the upper layer of the seed layer 161 or within a predetermined distance from the seed layer 161.

As illustrated in FIGS. 4A to 4C and FIG. 8B, after the substrate 110 is placed in the plating bath, a predetermined voltage may be applied to the seed layer 161, so that the plating layer 162 may be grown using the seed layer 161 exposed by the photosensitive pattern 155 as a seed.

The photosensitive pattern 155 may be patterned considering the undercut structure 151 of the connection structure 105A. For example, the upper side of the photosensitive pattern 155 may be positioned closer to the seed layer 161 than the lower side.

The thickness of the photosensitive pattern 155 may determine the size of the open depth D of the undercut structure 151. The open depth D of the undercut structure 151 may be expressed by Equation 1.

D=PD1−PD2 [Equation 1]

PD1 may represent the thickness of the plating layer 162, and PD2 may represent the thickness PD2 of the photosensitive pattern 155.

In this instance, the open depth D may be equal to the thickness PD1 of the plating layer 162 on the upper surface of the photosensitive pattern 155, but is not limited thereto.

The plating layer 162 may comprise a metal such as copper (Cu). The copper may be easy to plate, may have low resistance, and may be strong in dry etching.

The plating process may be performed until the plating layer 162 is grown on the upper surface of the photosensitive pattern 155. The edge of the surface of the plating layer 162 grown on the upper surface of the photosensitive pattern 155 may have a round shape.

As illustrated in FIGS. 4A to 4C and FIG. 8C, by removing the photosensitive pattern 155, a mushroom-structured plating layer 162 having an undercut structure 151 and a round shape at the edge of the surface thereof may be formed.

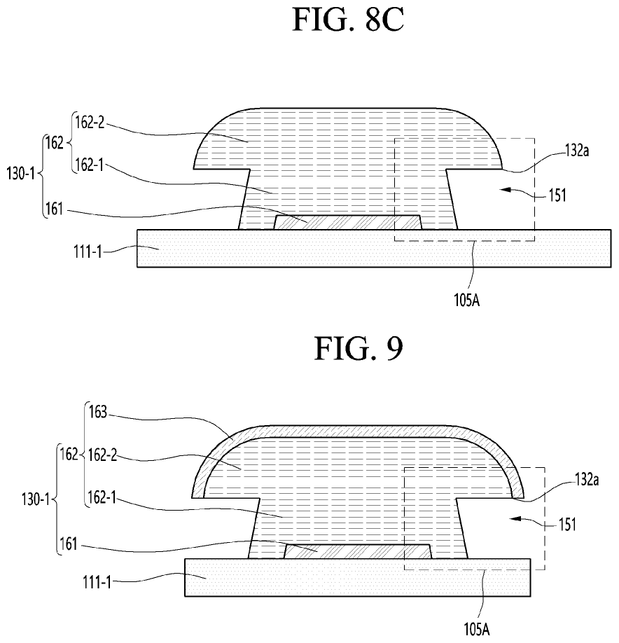

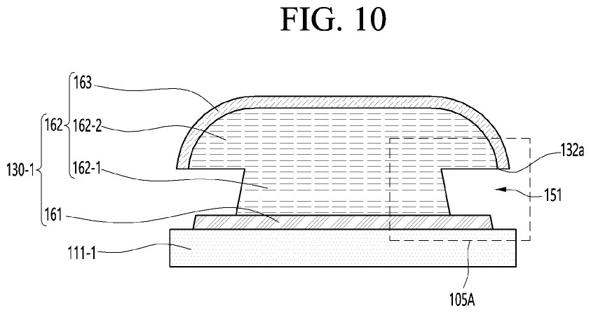

FIG. 9 is a cross-sectional view illustrating an organic light-emitting display device according to a third embodiment. FIG. 10 is a cross-sectional view illustrating an organic light-emitting display device according to a fourth embodiment. The third embodiment and the third embodiment are the same as the second embodiment (FIG. 7) except for the cover layer 163. The same drawing reference numerals are given to components having the same shape, structure, and/or function as those of the second embodiment in the third embodiment and the fourth embodiment, and detailed descriptions thereof are omitted.

In the third embodiment (FIG. 9) and the fourth embodiment (FIG. 10), the first protrusion part 130-1 may comprise a cover layer 163 on the plating layer 162.

The cover layer 163 may be formed by oxidizing the surface of the plating layer 162. When the plating layer 162 is oxidized, an oxide layer such as CuOx may be formed. Therefore, the cover layer 163 may comprise an oxide layer. Since the oxide layer has a black color, it may also be used as a black matrix (layer). Usually, a black matrix (layer) may be disposed between the subpixels, so that color mixing may be prevented. For this purpose, a black matrix (layer) is provided separately between the subpixels.

However, according to the embodiment, since the cover layer 163 is used as a black matrix (layer), there is no need to form a separate black matrix, so that material costs can be reduced, the process can be simplified, and the product thickness can be reduced.

In the third embodiment (FIG. 9), the width of the seed layer 161 may be smaller than the width of the lower region 162-1 of the plating layer 162. In this instance, the plating layer 162 may cover the seed layer 161. The plating layer 162 may be disposed on the upper surface and the side surface of the seed layer 161.

In the fourth embodiment (FIG. 10), the width of the seed layer 161 may be greater than the width of the lower region 162-1 of the plating layer 162. In this instance, the central region of the seed layer 161 may vertically overlap with the plating layer 162, and the edge region of the seed layer 161 may not vertically overlap with the plating layer 162.

Since the seed layer 161 comprises a metal, the seed layer 161 may also be used as an auxiliary electrode AC. Therefore, even if the cathode electrode 123g of the organic light-emitting element 120g is not in contact with the plating layer 162 but only with the seed layer 161, it may be electrically connected to the first power line (PL1 of FIGS. 1 and 3) through the seed layer 161, which is the auxiliary electrode AC.

1. An organic light-emitting display device, comprising:
a bank between subpixels on a substrate;
an anode electrode on the subpixel;
an organic light-emitting layer on the anode electrode and the bank;
a cathode electrode on the organic light-emitting layer;
a protrusion part disposed on an upper side of the bank so as to be spaced apart from the organic light-emitting layer,
wherein the protrusion part comprises:
a first layer on the bank;
a second layer on the first layer;
a third layer below the first layer; and
an etch-stop layer on second layer,
wherein a side portion of the third layer is positioned on a same vertical line or diagonal line as a side portion of the second layer or is configured to extend from a side portion of the second layer in a direction of the subpixel, and,
wherein a side portion of the first layer is recessed into an inside of the protrusion part from the side portion of the second layer.

2. The organic light-emitting display device of claim 1, wherein the protrusion part has a connection structure comprising an auxiliary electrode electrically connected to the cathode electrode, and
wherein the etch-stop layer is disposed on the connection structure.

3. (canceled)

4. (canceled)

5. (canceled)

6. (canceled)

7. (canceled)

8. (canceled)

9. The organic light-emitting display device of claim 2, wherein at least one of the first layer, the second layer, or the third layer is the auxiliary electrode.

10. (canceled)

11. (canceled)

12. (canceled)

13. The organic light-emitting display device of claim 1, further comprises:
an open structure configured to induce a hole injection layer of the organic light-emitting layer to be isolated in the bank.

14. The organic light-emitting display device of claim 1, wherein the etch-stop layer is disposed on the side portion of the second layer.

15. The organic light-emitting display device of claim 1, wherein the etch-stop layer is disposed on the side portion and a lower side of the second layer.

16. The organic light-emitting display device of claim 1, wherein the etch-stop layer comprises comprising one of ITO, Al₂O₃, Cu, and CuOx.

17. The organic light-emitting display device of claim 1, wherein the etch-stop layer comprises a first etch-stop layer and a second etch-stop layer, and wherein the first etch-stop layer comprises comprising one of ITO, Al₂O₃, Cu, and CuOx.

18. The organic light-emitting display device of claim 17, wherein the first etch-stop layer is disposed on the second layer, and wherein the second etch-stop layer is disposed between the second layer and the first etch-stop layer.

19. The organic light-emitting display device of claim 18, wherein the first etch-stop layer is disposed on a lower side of the second layer via a side portion of the second etch-stop layer.

20. An organic light-emitting display device, comprising:
a bank between subpixels on a substrate;
an anode electrode on the subpixel;
an organic light-emitting layer on the anode electrode and the bank;
a cathode electrode on the organic light-emitting layer;
a protrusion part disposed on an upper side of the bank so as to be spaced apart from the organic light-emitting layer,
wherein the protrusion part has a connection structure comprising an auxiliary electrode electrically connected to the cathode electrode,
wherein the protrusion part comprises:
a first layer on the bank;
a second layer on the first layer;
a third layer below the first layer; and
an etch-stop layer on second layer,
wherein a side portion of the third layer is positioned on a same vertical line or diagonal line as a side portion of the second layer or is configured to extend from a side portion of the second layer in a direction of the subpixel, and,
wherein a side portion of the first layer is recessed into an inside of the protrusion part from the side portion of the second layer.

21. The organic light-emitting display device of claim 20, wherein the etch-stop layer comprises one of ITO, Al₂O₃, Cu, and CuOx.
